(19) United States
(12) Patent Application Publication
(10) Pub. No.: US 2013/0256734 A1
(43) Pub. Date: Oct. 3, 2013

(54) LIGHT-EMITTING DIODE AND METHOD FOR MANUFACTURING THE SAME

(71) Applicants: SUNG-HSIANG YANG, Chu-Nan (TW); WEI-CHUN YEH, Chu-Nan (TW); CHENG-CHAO CHAO, Chu-Nan (TW)

(72) Inventors: SUNG-HSIANG YANG, Chu-Nan (TW); WEI-CHUN YEH, Chu-Nan (TW); CHENG-CHAO CHAO, Chu-Nan (TW)

(21) Appl. No.: 13/629,654

(22) Filed: Sep. 28, 2012

(30) Foreign Application Priority Data
Mar. 29, 2012 (TW) 101111049

(51) Int. Cl. H01L 33/64

(52) U.S. Cl. 257/99; 438/26; 257/E33.059

(57) ABSTRACT

An LED (light emitting diode) includes a base, two spaced electrodes and a thermal conductivity layer. The base has a top surface. The two electrodes and the thermal conductivity layer are located on the top surface of the base. The thermal conductivity layer is attached to the top surface and located beside and between the electrodes. The two electrodes are electrically insulated from each other, and electrically insulated from the thermal conductivity layer. A light emitting chip is electrically connected to the two electrodes. The electrodes and the thermal conductivity layer are on different levels.

### BACKGROUND

1. Technical Field

The present disclosure relates to a light-emitting diode (LED) and a method for manufacturing the LED.

2. Description of Related Art

LEDs have been widely promoted as a light source of electronic devices owing to many advantages, such as high luminosity, low operational voltage and low power consumption. In practice, the LED generally includes a base, two electrodes located on the base, a light-emitting chip electrically connected with the two electrodes, and an encapsulation sealing the electrodes and the light-emitting chip. The electrodes are made of metal which has good thermal conductivity, whereby the electrodes can take away part of the heat generated by the light-emitting chip. However, the electrodes each have a limited area, whereby the heat dissipating efficiency of the LED by the electrodes is not good enough.

Therefore, an LED and a method for manufacturing the LED capable of overcoming the above described shortcoming is desired.

### BRIEF DESCRIPTION OF THE DRAWINGS

Many aspects of the present disclosure can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a schematic view of an LED in accordance with one embodiment of the present disclosure.

FIG. 2 is an exploded view of the LED of FIG. 1.

FIG. 3 is a flow chart showing a method for manufacturing an LED in accordance with a first embodiment of the present disclosure.

FIG. 4 shows first and second steps of the method for manufacturing the LED of FIG. 3.

FIGS. 5 and 6 show a third step of the method for manufacturing an LED of FIG. 3.

FIG. 7 is an isometric view of a substrate with a metal sheet manufactured by the first to third steps of the method of FIGS. 3-6.

FIG. 8 is a bottom view of a mold applied in a method for manufacturing an LED in accordance with a second embodiment of the present disclosure.

FIG. 9 is an isometric view of a substrate with a metal sheet manufactured by the method of FIG. 8.

FIG. 10 is a schematic view of a method for manufacturing an LED in accordance with a third embodiment of the present disclosure.

### DETAILED DESCRIPTION

Embodiment of the present LED and the method for making the LED will now be described in detail below and with reference to the drawings.

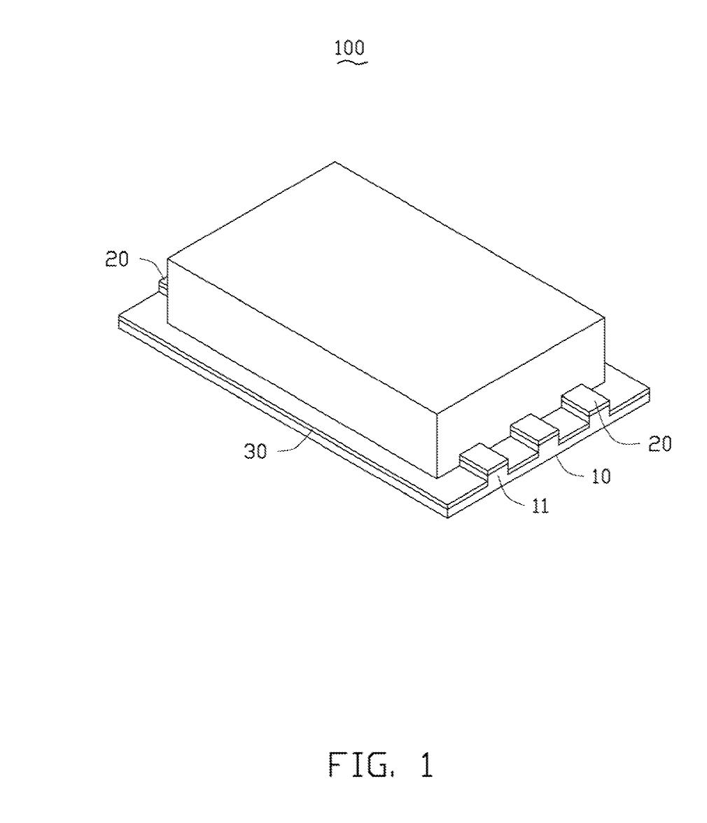

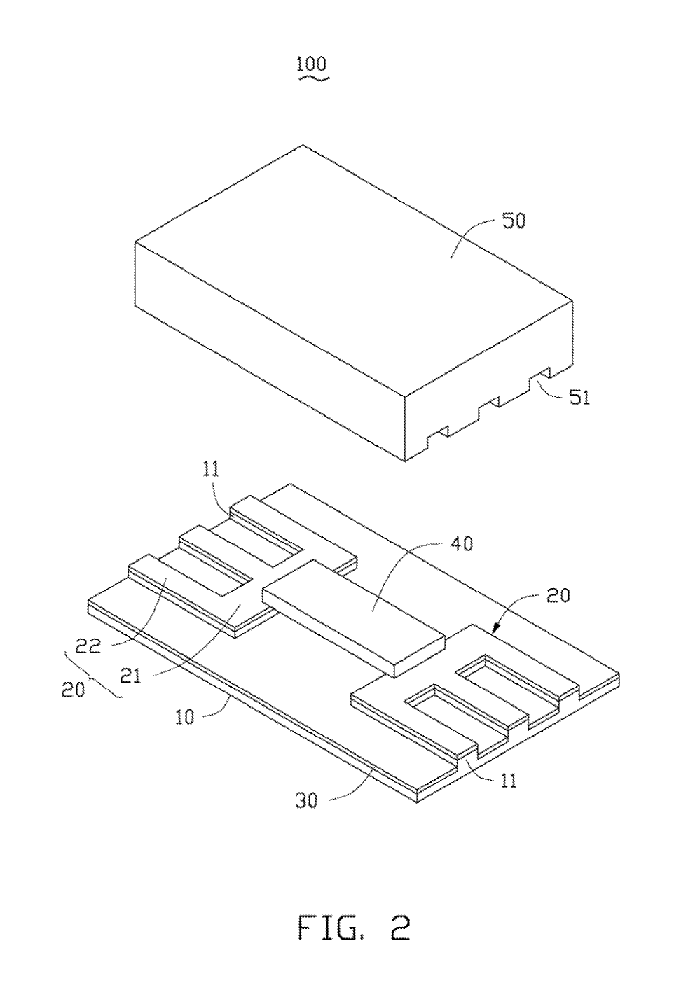

Referring to FIGS. 1 and 2, an LED (light emitting diode) 100 in accordance with a first embodiment of the present disclosure includes a base 10, two electrodes 20 located on the base 10, a thermal conductivity layer 30 located on the base 10 and electrically insulating from the two electrodes 20, a light-emitting chip 40 electrically connected with the two electrodes 20, and an encapsulation 50 sealing the light-emitting chip 40.

The base 10 is a rectangular plate and made of electrically insulating material, such as plastic or silicone. Two spaced protrusions 11 extend from a top surface of the base 10, and each of the protrusions 11 has an E-shaped configuration as viewed from a top of the base 10. The two protrusions 11 are arranged in mirror symmetry. The two electrodes 20 are located on top surfaces of the two protrusions 11, respectively. Each electrode 20 has a configuration matching that of the corresponding protrusion 11. A remaining part of the top surface of the base 10 without the protrusions 11 is lower than the top surfaces of the protrusions 11, and the thermal conductivity layer 30 is located on the remaining part of the top surface of the base 10. A height difference between the top surface of each protrusion 11 and the top surface of the base 10 is greater than twice the thickness of the thermal conductivity layer 30, so the electrode 20 located on the top surface of each protrusion 11 is apart and electrically insulated from the thermal conductivity layer 30.

A shape of each electrode 20 is the same as the corresponding protrusion 11 of the base 10. That is to say, each electrode 20 also has an E-shaped configuration as viewed from the top of the base 10, so each electrode 20 entirely covers the top surface of the corresponding protrusion 11. Each electrode 20 includes a connection portion 21 and three branches 22 extending from one side of the connection portion 21. The two connection portion 21 of the two electrodes 20 are adjacent to each other, in order to be electrically connected with two electrical contacts of the light-emitting chip 40. The branches 22 of the two electrodes 20 are extending along opposite directions from the two connection portions 21, respectively. The electrodes 20 and the thermal conductivity layer 30 are made of the same metal material, such as copper or aluminum.

The two electrical contacts of the light-emitting chip 40 are electrically connected to the two electrodes 20, respectively, by soldering, wherein soldering balls are formed on the two electrical contacts of the light-emitting chip 40, which are melted to connect with the two electrodes 20 by surface mounting technology. Alternatively, the light-emitting chip 40 can also be electrically connected to the two electrodes 20 by wire boding or eutectic bonding.

The encapsulation 50 is substantially cuboid-shaped, covers the light-emitting chip 40, the two electrodes 20 and the thermal conductivity layer 30, and seals the light-emitting chip 40 therein. The encapsulation 50 is made of heat-resistant and translucent material, such as plexiglass or epoxy resin. The free ends of the branches 22 of the two electrodes 20 extend outward from opposite sides of the encapsulation 50 to electrically with an external circuit structure (not shown) thereby to obtain external power for driving the light-emitting chip 40. The peripheral portion of the thermal conductivity layer 30 is uncovered by the encapsulation 50 and exposed to air, thus facilitating dissipation of heat from the thermal conductivity layer 30 to air.

In the LED 100, the top surface of the base 10 facing to the light-emitting chip 40 is entirely covered by the electrodes 20 and the thermal conductivity layer 30; therefore, the heat generated by the LED 100 can be efficiently transferred to outside via the electrodes 20 and the thermal conductivity layer 30, whereby the heat dissipating efficiency of the LED 100 is improved.

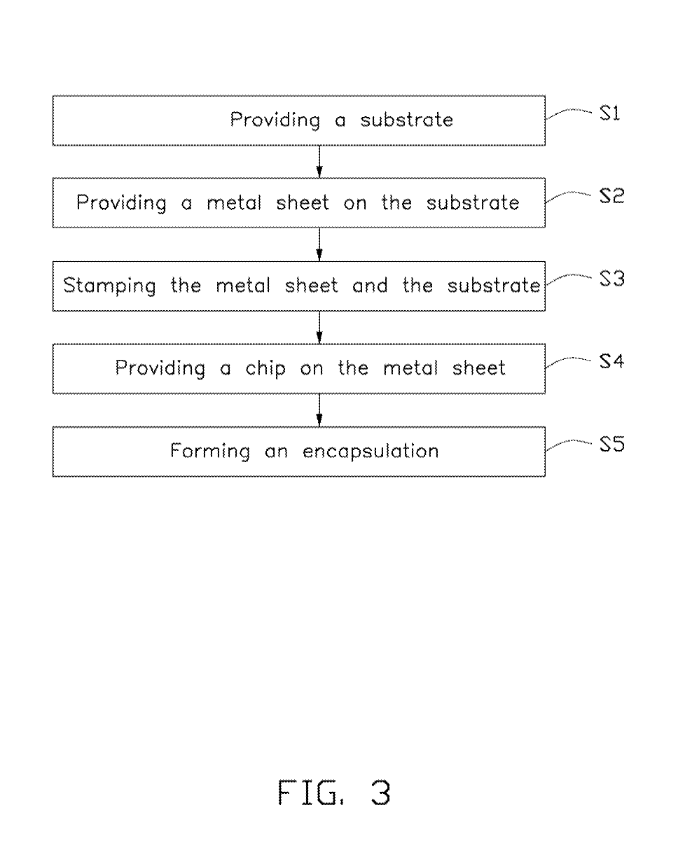

Referring to FIG. 3, a flow chart of a method for manufacturing the LED 100 in accordance with a first embodiment of the present disclosure is shown.

The LED 100 can be manufactured in following steps.

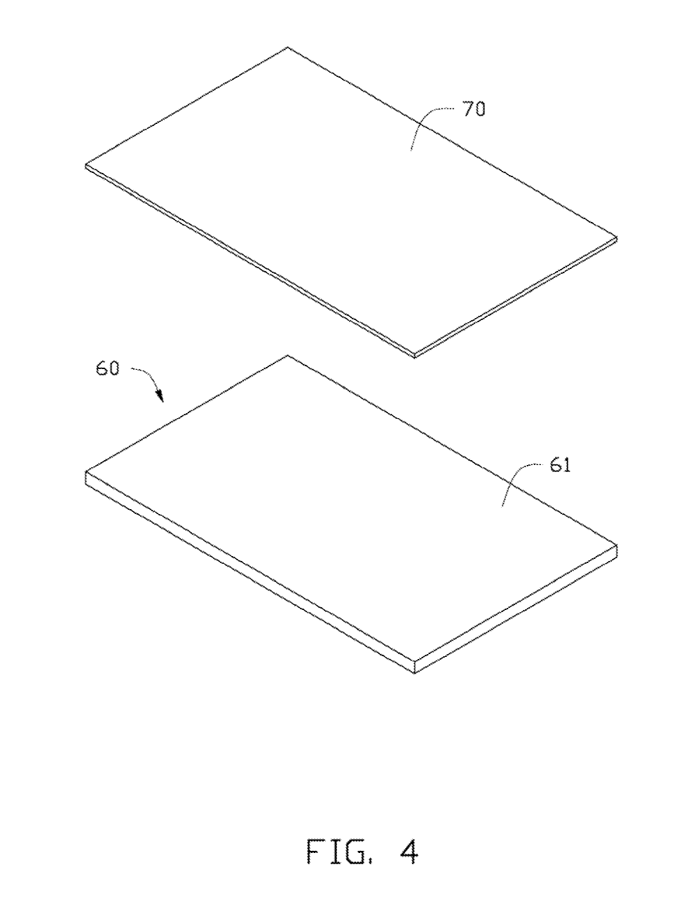

As shown in FIG. 4, a substrate 60 is provided. The substrate 60 is a rectangular plate and includes a flat top surface 61. The substrate 60 is made of electrically insulating material and is deformable. The material can be epoxy resin, polyether sulfone resin, polyethylene or polytetrafluoroethylene.

A metal sheet 70 is provided on the substrate 60, such as a copper or an aluminum sheet, and the metal sheet 70 entirely covers the top surface 61 of the substrate 60.

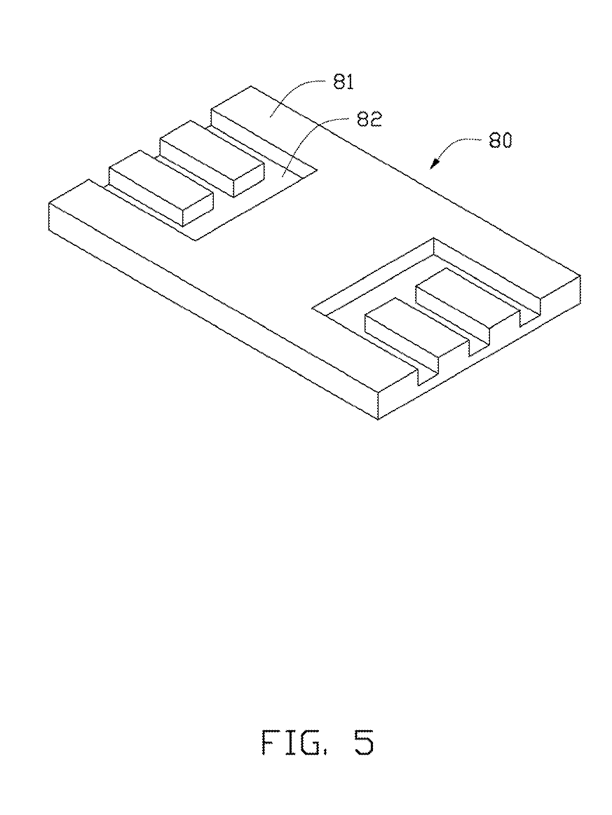

As shown in FIG. 5, a stamping mold 80 is provided. The stamping mold 80 has a stamping surface 81, and the stamping surface 81 defines two spaced grooves 82 therein. The grooves 82 are both E-shaped, and arranged in mirror symmetry, as viewed from a bottom of the stamping mold 80. A depth of each groove 82 is greater than twice the thickness of the metal sheet 70.

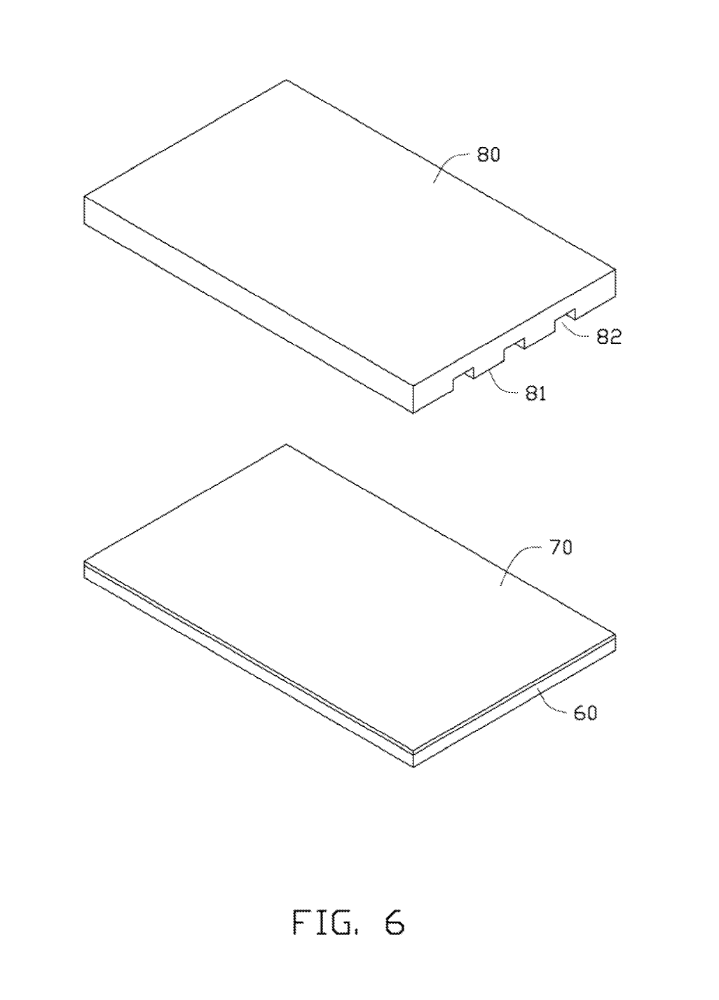

As shown in FIG. 6, the stamping surface 81 of the stamping mold 80 is arranged facing the metal sheet 70 and the flat top surface 61 of the substrate 60, and the stamping mold 80 is heated. Then the metal sheet 70 and the substrate 60 are pressed by the stamping mold 80.

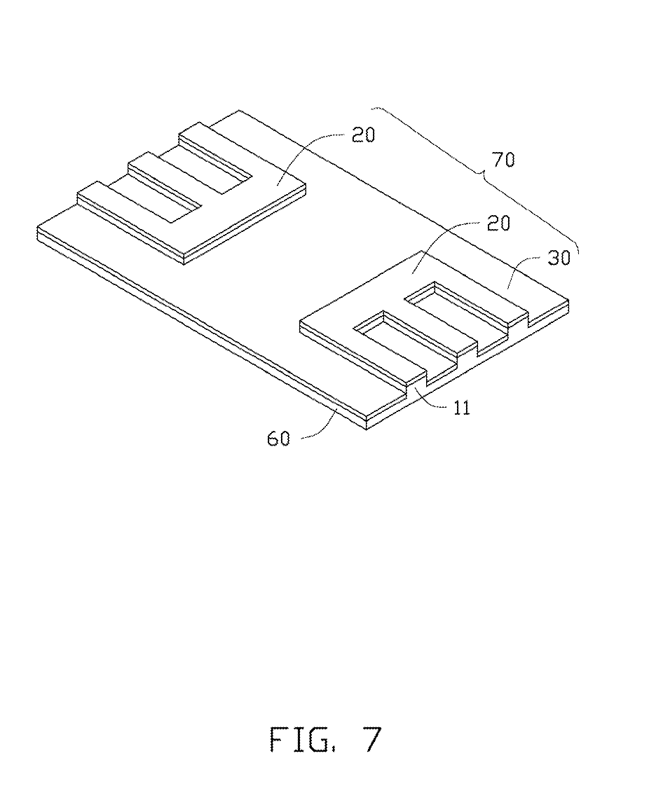

As shown in FIG. 7, the metal sheet 70 is divided into two E-shaped electrodes 20 and a thermal conductivity layer 30 located beside and generally between the two electrodes 20. The two electrodes 20 are formed at positions corresponding to those of the two grooves 82 of the stamping mold 80. The stamping surface 81 of the stamping mold 80 thermally presses the top surface 61 of the substrate 60 via the thermal conductivity layer 30, so the top surface 61 is depressed. Two protrusions 11 are formed at positions corresponding to the grooves 82 of the stamping mold 80, respectively, and bottom surfaces of the electrodes 20 are securely attached to top surfaces of the protrusions 11, respectively. So, the substrate 60 is shaped into the base 10 of the LED 100 by the pressing of the stamping mold 80 to the substrate 60.

A light-emitting chip 40 is provided on the base 10. The light-emitting chip 40 is electrically connected to the two electrodes 20 by flip chip bonding, with two electrical contacts formed on a bottom surface of the light-emitting chip 40 being soldered to the two electrodes 20, respectively.

An encapsulation 50 is formed on the light-emitting chip 40. The encapsulation 50 covers the top surface of the thermal conductivity layer 30 and seals the light-emitting chip 40 and the electrodes 20. In this embodiment, the bottom surface of the encapsulation 50 facing the light-emitting chip 40 defines a receiving groove 51 for receiving the light-emitting chip 40, the electrodes 20 and the protrusions 11 therein. The encapsulation 50 is made of heat-resistant and translucent material, such as plexiglass or epoxy resin. The encapsulation 50 can be formed in advance and then adhered to the top surface of the base 10. Alternatively, the encapsulation 50 can be injection molded onto the top surface of the base 10. In addition, a phosphor (not shown) can be mixed in the encapsulation 50 to obtain a desired color of light of the LED 100.

In the process, the electrodes 20 are formed on the base 10 by the way of stamping without using any chemical, thereby avoiding environment pollution. Further, the remaining part of the metal sheet 70 besides the electrodes 20 is utilized to constitute the thermal conductivity layer 30, thereby avoiding material waste and improving the heat dissipating efficiency of the LED 100.

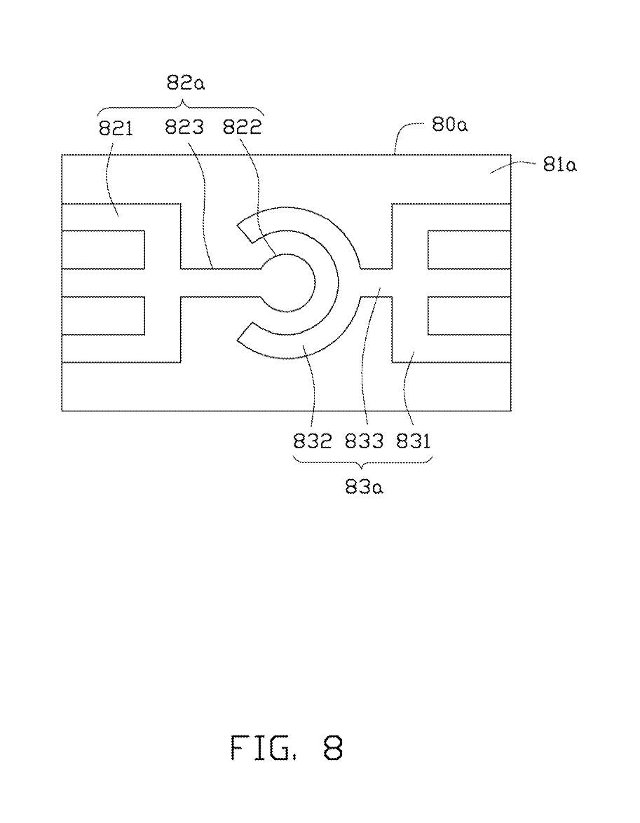

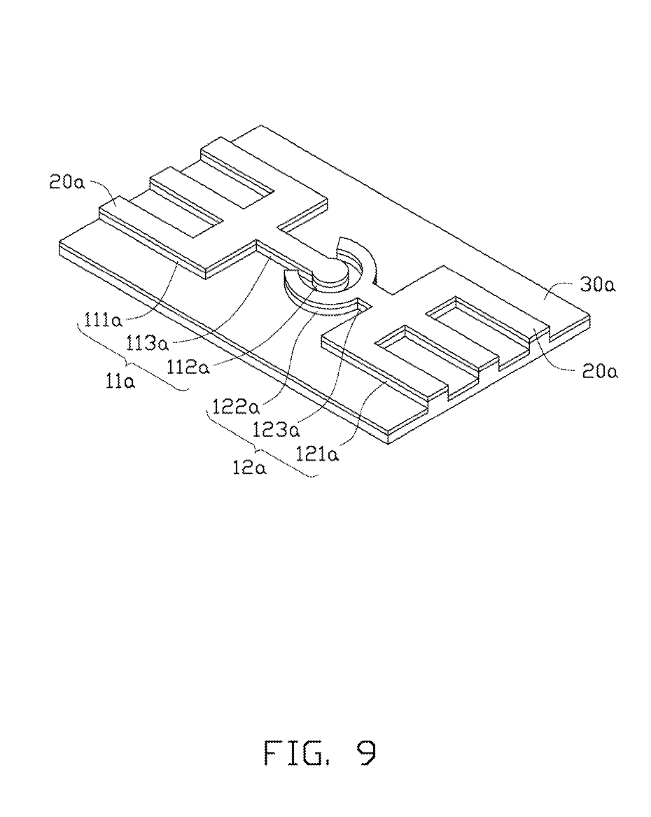

The shapes of the electrodes 20 and the protrusions 11 of the base 10 can be adjusted by changing the shapes of the grooves 82 of the stamping mold 80. Referring to FIG. 8, a stamping mold 80a of a method for manufacturing an LED in accordance with a second embodiment of the present disclosure has a stamping surface 81a. The stamping surface 81a defines two spaced grooves 82a, 83a, and a shape of the groove 82a is different from that of the groove 83a. The groove 82a includes an E-shaped first lateral groove 821, a circular first inside groove 822 and a first connecting groove 823 interconnecting the first lateral groove 821 and the first inside groove 822. The groove 83a includes an E-shaped second lateral groove 831, a sector second inside groove 832 and a second connecting groove 833 interconnecting the second lateral groove 831 and the second inside groove 832. The second inside groove 832 is configured surrounding the first inside groove 822. Referring to FIG. 9, correspondingly, the two protrusions 11a, 12a processed by the stamping mold 80a are different in shape. The protrusion 11a includes an E-shaped first lateral portion 111a, a circular first inside portion 112a and a first connecting portion 113a interconnecting the first lateral portion 111a and the first inside portion 112a. The protrusion 12a includes an E-shaped second lateral portion 121a, a sector second inside portion 122a and a second connecting portion 123a interconnecting the second lateral portion 121a and the second inside portion 122a. The second inside portion 122a is configured surrounding the first inside portion 112a. The two electrodes 20a processed by the stamping mold 80a correspond to the two protrusions 11a, 12a respectively.

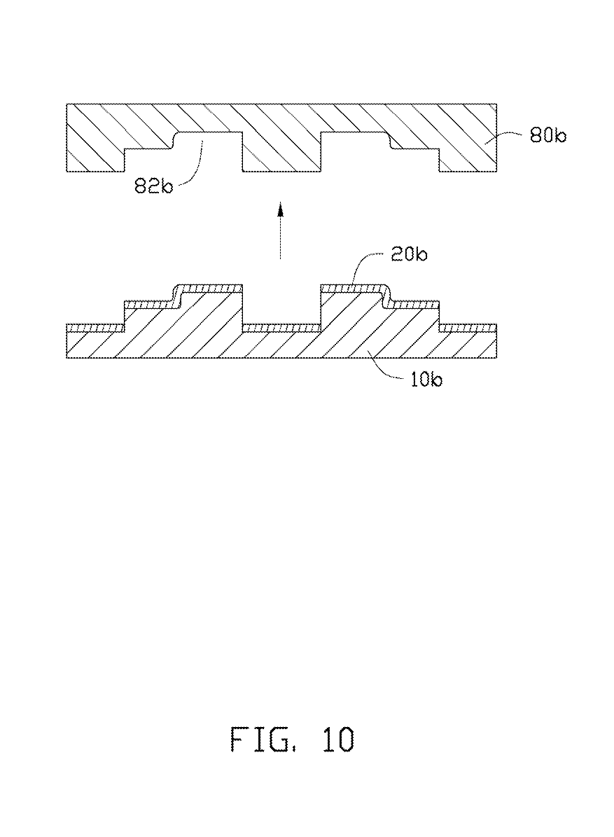

In the previous embodiments, the two electrodes 20, 20a each have a flat structure. Referring to FIG. 10, a stamping mold 80b of a method of manufacturing an LED in accordance with a third embodiment is provided. The depths of different areas of each groove 82b of the stamping mold 80 are different, so the electrodes 20b each can be formed with a step-like structure.

Particular embodiments are shown and described by way of illustration only. The principles and the features of the present disclosure may be employed in various and numerous embodiments thereof without departing from the scope of the disclosure as claimed. The above-described embodiments illustrate the scope of the disclosure but do not restrict the scope of the disclosure.

What is claimed is:

1. An LED (light emitting diode), comprising:
a base comprising a top surface;
two spaced electrodes on the top surface of the base and electrically insulating from each other; and
a thermal conductivity layer also on the top surface of the base and separated and electrically insulating from the electrodes, the thermal conductivity layer being located beside and between the two electrodes; and
a light emitting chip electrically connected to the electrodes.

2. The LED of claim 1, wherein the electrodes and the thermal conductivity layer are made of the same metallic material.

3. The LED of claim 1, wherein two spaced protrusions extend from the top surface of the base, the electrodes are located on top surfaces of the two protrusions, and a top surface of each of the electrodes is higher than that of the thermal conductivity layer.

4. The LED of claim 3, wherein a height difference between the top surface of each protrusion and the top surface of the base is greater than twice a thickness of the thermal conductivity layer.

5. The LED of claim 3, wherein each electrode and a corresponding protrusion are all E-shaped, each electrode comprises a connection portion and a plurality of branches extending from one side of the connection portion, the connection portions of the two electrodes are adjacent to each other, and the branches of the two electrodes extend along opposite directions and away from each other.

6. The LED of claim 3, wherein the two protrusions are different in shape, one of the protrusions includes an E-shaped first lateral portion, a circular first inside portion and a first connecting portion interconnecting the first lateral portion and the first inside portion, the other one of the protrusions includes an E-shaped second lateral portion, a sector second inside portion and a second connecting portion interconnecting the second lateral portion and the second inside portion, and the second inside portion is configured surrounding the first inside portion.

7. The LED of claim 3, wherein each of the electrodes is formed with a step-shaped structure.

8. The LED of claim 1, further comprising an encapsulation sealing the light-emitting chip, free ends of the two electrodes extending out of opposite sides of the encapsulation, and a peripheral portion of the thermal conductivity layer being exposed from the encapsulation.

9. The LED of claim 1, wherein the top surface of the base is entirely covered by the electrodes and the thermal conductivity layer.

10. The LED of claim 1, wherein the base is made of electrically insulating material.

11. A method for manufacturing an LED, comprising steps of:
step 1: providing a substrate, the substrate comprising a flat top surface, the substrate being made of electrically insulating material and being deformable;
step 2: covering a metal sheet on the top surface of the substrate;
step 3: providing a stamping mold to press the metal sheet and the substrate, the metal sheet being divided into two electrodes and a thermal conductivity layer by the pressing operation of the stamping mold to the metal sheet and the substrate, the thermal conductivity layer being attached to the top surface of the substrate at a position beside and between the electrodes, one of the two electrodes being electrically insulated from the other one, the two electrodes being electrically insulated from the thermal conductivity layer; and
step 4: providing a light-emitting chip and electrically connecting the light-emitting chip with the two electrodes.

12. The method of claim 11, wherein the stamping mold has a stamping surface, the stamping surface defines two spaced grooves therein, the two electrodes are formed in the two grooves of the stamping mold, respectively, the stamping surface of the stamping mold hot presses the top surface of the substrate via the metal sheet, two protrusions are formed in the grooves of the stamping mold, respectively, and bottom surfaces of the electrodes are securely attached to top surfaces of the protrusions, respectively.

13. The method of claim 12, wherein a depth of each groove is greater than twice a thickness of the metal sheet.

14. The method of claim 12, wherein the grooves are both E-shaped, and arranged in mirror symmetry.

15. The method of claim 12, wherein the two spaced grooves are different from each other, one of the grooves comprises an E-shaped first lateral groove, a circular first inside groove and a first connecting groove interconnecting the first lateral groove and the first inside groove, and the other one of the grooves comprises an E-shaped second lateral groove, a sector second inside groove and a second connecting groove interconnecting the second lateral groove and the second inside groove, and the second inside groove is configured surrounding the first inside groove.

16. The method of claim 12, wherein depths of different areas of each groove of the stamping mold are different.

17. The method of claim 11, further comprising a step 5 of providing an encapsulation to seal the light-emitting chip therein.

18. The method of claim 17, wherein the encapsulation covers a top surface of a part of the thermal conductivity layer and a part of the electrodes.
